(19) United States
(12) Patent Application Publication
(10) Pub. No.: US 2011/0108103 A1
(43) Pub. Date: May 12, 2011

(54) SOLAR CELL

(76) Inventor: Jan Tuma, Herrenberg (DE)

(21) Appl. No.: 12/734,474

(22) PCT Filed: Nov. 4, 2008
(86) PCT No.: PCT/EP2008/009282

§ 371 Date: May 4, 2010

(30) Foreign Application Priority Data
Nov. 7, 2007 (DE) 10 2007 052 928.9

(51) Int. Cl. H01L 31/0216; H01L 31/02

(52) U.S. Cl. 136/256; 136/252

(57) ABSTRACT

The invention relates to a solar cell (1) having a flexible substrate (10), preferably composed of a polymer plastic, and having at least one photovoltaic layer (26), which is applied to the substrate (10) for conversion of solar energy to electrical energy, characterized in that the substrate (10) has, integrally, adhesive closing elements (12) by means of which the substrate (10) and with it the solar cell (1) can be fixed on a mount device (20) without the use of tools.

The invention relates to a solar cell having a flexible substrate and having at least one photovoltaic layer applied to the substrate for converting solar energy into electrical energy.

Solar cells such as these are conventionally produced in thin-film technology, for example, monolithically integrated in single-crystalline silicon wafers, or are produced using deposited polycrystalline or amorphous silicon layers. The photovoltaic active principle is based on the incident sunlight in the photovoltaic layer releasing charge carriers which are conducted separately to each respective electrode, and, as a result, an electrical voltage arises on the electrodes. Both production and mounting of the known solar cells are associated with high investment and installation costs which to date have been an obstacle to the large-scale use of solar cells.

DE 103 05 938 A1 discloses a flexible thin-film solar cell which is produced by application of energy-converting layers to a flexible material and providing it with a versatile adhesive material such as a cement.

DE 196 46 318 A1 discloses an efficient method for producing a touch-and-close fastener part from thermoplastic.

DE 10 2004 003 123 A1 discloses a touch-and-close fastener part with an illuminant and a method for producing such a touch-and-close fastener part.

The object of the invention is to make available a solar cell which overcomes the disadvantages of the prior art, and enabling, in particular, the economical generation of solar current by the economical production and mounting of solar cells. In one embodiment, the attachment of the solar cell to a carrier means is to be simplified and, hence, the functionality and potential applications of solar cells according to the invention are also to be improved.

The object is achieved by the solar cell specified in claim 1. Special embodiments of the invention are defined in the dependent claims.

In one embodiment, the solar cell has a flexible and therefore pliable and, preferably, also elastically deformable substrate on which at least one photovoltaic layer for converting solar energy into electrical energy is applied. Several photovoltaic layers can also be applied. Fundamentally, the flexible substrate can be produced in any manner, for example, it can be a substrate produced by knitting or weaving, as is used, for example, in the textile industry. In one embodiment, the substrate is formed by a flat polymer plastic, for example by a polymer plastic film. It is also possible to use a sandwich structure, having, for example, a component produced by knitting or weaving with an at least unilateral and preferably blanket coating with a polymer plastic.

One photovoltaic layer or several photovoltaic layers can be applied to the substrate, for example, by conventional production processes of thin-film technology or thick-film technology. The use of organic, particularly polymer photovoltaic layers, is especially advantageous since they have especially high flexibility and thus the entire solar cell has high flexibility. The photovoltaic absorber layers can be, for example, semiconductor polymers such as poly-3-alkyl thiophenes, conjugated low bandgap polymers or polyphenylene vinylenes as p-conductive material and as n-conductors, for example, C60 fullerene derivatives.

In addition to the photovoltaic layers, the solar cell has electrodes with which the solar cell can make electrical contact and on which the photovoltage is present. Preferably, at least one of the electrodes is produced from a material which is transparent or partially transparent to the wavelength range of the radiation which is to be absorbed. The substrate can also be transparent or partially transparent so that the radiation to be absorbed can also be incident by way of the substrate side. Alternatively, an opaque or reflective substrate can also be used, or opaque or reflective layers can be applied to the substrate.

In one embodiment, there is a polymer intermediate layer between at least one of the electrodes and the adjacent photovoltaic absorber layer; this intermediate layer can be applied to the electrode by spin coating, can be based on doped polyethylene dioxythiophene and can have a thickness from 50 to 200 nm, in particular 80 to 100 nm. The polymer intermediate layer acts as a smoothing layer and contributes to improvement of charge carrier injection into the electrode.

In one embodiment, the electrodes can be arranged distributed on the substrate, in particular, the substrate can have electrode surfaces that are electrically connected to one another at different positions, particularly electrode surfaces arranged in a regular pattern so that the solar cell can make electrical contact not only at a given site, but at different positions. This is especially advantageous for large-area solar cells in which the possibility of different feed lines of connecting cables or contact with several connecting cables is advantageous.

In one embodiment, at least some of the layers applied to the substrate are applied by printing, especially silk-screen printing or offset printing, by precipitation from the gaseous phase or liquid phase, by vapor coating or spraying. The layers can be applied unstructured and, if necessary, by subsequent structuring, for example, using photolithographic steps, the applied layer can be structured. Especially in the case of silk-screen printing can the layers also be applied already structured.

In one embodiment, at least some of the layers are applied by an inkjet printing technique in which the layer to be applied is printed onto the substrate with high resolution directly or dissolved in a carrier material by means of a spray nozzle. For this purpose, a large selection of functional organic and inorganic inks is available, including dispersions or suspensions with solid objects which can produce the layers on the substrate by means of fine nozzles with diameters of a few hundred nanometers. In this way, electronic components or electronic circuits can also be applied to the substrate, by which the solar cell can be combined with an electrical circuit, or the electrical circuit can be produced integrated with the solar cell.

The substrate integrally has touch-and-close fastener elements, by means of which the substrate and therefore the solar cell can be attached to a carrier means without tools. The touch-and-close fastener elements form a single unit with the substrate. The attachment forces can be made available by mechanical hooking and/or by chemical bonding forces.

A forming method such as is described, for example, in DE 196 46 318 A1, can be used to produce touch-and-close fastener elements, in particular in one piece with the flat substrate, which enable mechanical hooking with the carrier means.

The touch-and-close fastener elements can be hook-shaped, mushroom-shaped, loop-shaped, or can have some other suitable hooking forms and can interact with the corresponding touch-and-close fastener elements of the carrier means. The touch-and-close fastener elements of the flat substrate and of the carrier means can be made identical or complementary to one another, for example, combinations of hook-hook, mushroom-mushroom, hook-loop, mushroom-loop, or the like are possible.

Alternatively or in addition, the touch-and-close fastener elements of the substrate can also interact with the surface of the carrier means by chemical binding forces, particularly by adhesion forces such as, for example, van der Waals forces or dipole forces. Stems, which are made integrally with the flat substrate, on their free end can be divided into a plurality of individual fibers, for example into several hundred fibers per stem.

The touch-and-close fastener elements can also be made such that the ends of the stems on their surface, which is oriented toward the surface of the carrier means, have an arch, preferably, a convex arch, and, preferably, the surface oriented toward the surface of the carrier means is widened relative to the adjoining region of the stem. The resulting narrowing of the ends of the stems defines a type of predetermined bending point which enables an alignment of the surface of the touch-and-close fastener elements, which surface is oriented toward the surface of the carrier means, to the surface of the carrier means and thus extensive contact of the touch-and-close fastener elements with the surface of the carrier means and/or enables detachment of the touch-and-close fastener elements from the carrier means with smaller forces. The end surfaces of the stems interact with the surface of the carrier means by adhesion forces and thus the substrate can be fastened on the carrier means. Suitable plastic materials for these touch-and-close fastener elements are inorganic and organic elastomers, in particular polyvinyl siloxane, and addition cross-linking silicone elastomers, also in the form of two-component systems, as well as acrylates. The use of rubber materials is also possible.

In one special embodiment of the invention, the touch-and-close fastener elements are produced in part without forming tools. One pertinent method is described in DE 100 65 819 C1 and DE 101 06 705 C1. Here, a plastic material is deposited by means of at least one application device in successively released droplets, and the locations of deposition of the droplets can be chosen to be three-dimensional with respect to the shape of the touch-and-close fastener elements to be formed. In this way, hook elements, mushroom elements, loop elements, and the like, can be produced with great freedom of shape, for example, in the form of an inkjet printing process.

The fastening of the solar cell according to the invention to the carrier means and preferably also detachment from the carrier means are simple and possible without tools. The fasteners can be easily produced in the form of a hook and loop fastener, over a large area and/or in very large numbers and therefore economically, and enable permanently reliable fastening of even large-area solar cells.

In one embodiment, the flat substrate is produced from a plastic, in particular from a thermoplastic. Alternatively, the first flat substrate can also be produced from a duroplastic, especially in the case of touch-and-close fastener elements produced without forming tools. The touch-and-close fastener elements preferably consist of the same material as the first flat substrate. Basically, particularly polyethylene and polypropylene are possible. Moreover, a plastic material can be chosen that has been selected from the group of acrylates such as polymethacrylates, polyethylene, polypropylene, polyoxymethylene, polyvinylidene fluoride, polymethylpentene, polyethylene chlorotrifluoroethylene, polyvinyl fluoride, polyethylene oxide, polyethylene terephthalates, polybutylene terephthalates, nylon 6, nylon 66 and polybutene. Alternatively, the substrate is produced from an inorganic and organic elastomer, in particular from polyvinyl siloxane, or an addition cross-linking silicone elastomer.

In one embodiment, the touch-and-close fastener elements are located on the side of the substrate opposite the photovoltaic layer. Especially in the case of a substrate which is transparent or partially transparent to the incident light, the touch-and-close fastener elements can also be located on the two sides of the substrate, or two substrates which each have touch-and-close fastener elements can be connected to one another, and the touch-and-close fastener elements can project on the two outer sides of the substrate combination and the photovoltaic layer can be located between the two substrates.

In one embodiment, not only can the solar cells according to the invention be fastened to carrier means of almost any shape without tools, for example to motor vehicle bodies, building facades, or garden furniture, but both attachment and detachment of the solar cell from the carrier means can take place without tools. The elimination of a separate connecting means, in particular of an adhesive or other fastener, simplifies attachment, especially without intervention in the carrier means. If adhesion is based on adhesive forces, the attachment primarily to smooth surfaces, such as, for example, panes of glass, is especially easily and reliably possible.

In one embodiment, the solar cells according to the invention can be produced in an especially economical roll-to-roll production process. Consequently, solar cells can be produced with large areas and at the same time at low cost, and, with a suitable arrangement of the terminal electrodes, especially with terminal electrodes which are located distributed on the substrate and which are electrically connected to one another, the solar cells can be suitably cut to size after application to the carrier means.

In one embodiment, the touch-and-close fastener elements are connected not only integrally to the substrate, for example by a film with the corresponding touch-and-close fastener elements being laminated to the flexible substrate of the solar cell, but the touch-and-close fastener elements are even made in one piece with the substrate which bears the photovoltaic layer. In this case, the solar cell can be mounted on a film-like flexible substrate which has touch-and-close fastener elements by depositing the electrodes and photovoltaic layers, particularly within the framework of a roll-to-roll production method. Production costs thus can be further reduced.

In one embodiment, the substrate on at least one attachment surface, preferably blanketed, has a plurality of touch-and-close fastener elements with a density of more than 100 touch-and-close fastener elements per cm². In a regular arrangement of touch-and-close fastener elements, this corresponds to a grid size of less than 1 mm. Preferably, the substrate has a density of more than 2,500 touch-and-close fastener elements per cm². In a regular arrangement of touch-and-close fastener elements, this corresponds to a grid size of less than 0.2 mm. Furthermore, the substrate preferably has a density of more than 10,000 touch-and-close fastener elements per cm², this corresponds to a grid size of less than 0.1 mm. In particular, the solar cell has more than 40,000 touch-and-close fastener elements per cm², corresponding to a grid size of less than 50 μm. In one special embodiment, the solar cell has more than 250,000 touch-and-close fastener elements per cm², corresponding to a grid size of less than 20 μm. The large number of touch-and-close fastener elements can simplify both attachment and detachment and at the same time can produce a high adhesive force.

In one embodiment at least some of the touch-and-close fastener elements have an attachment section which is spaced apart from the substrate and which can be moved into flat contact with the carrier means as a result of the force due to weight acting on the solar cell and/or as a result of a contact pressure which can be applied manually such that the arising adhesion forces are sufficient to fasten the solar cell to the carrier means. The attachment section is preferably made flexibly pliable so that even when small forces are used, extensive contact with the carrier means and thus a high attachment force can be achieved by adhesion forces alone.

In one embodiment, the modulus of elasticity of the contact surfaces of the touch-and-close fastener elements is reduced relative to the bordering section of the touch-and-close fastener element. For this purpose, the touch-and-close fastener element, on its end facing the carrier means, can have a coating with a suitable material. The coating can be, for example, imprinted onto the touch-and-close fastener elements, or can be applied when the touch-and-close fastener elements are being produced, can be placed, for example, in a molding roller used for this purpose, or the touch-and-close fastener elements, which have been produced, can be dipped into a bath of a suitable material.

In one embodiment, at least some of the touch-and-close fastener elements are electrically conductive. Accordingly, it is possible to make electrical contact with the photovoltaic layer. The touch-and-close fastener elements are used as terminal electrodes and, for example, by adhesion to a metal electrode, such as, for example, a gold-coated electrode, they can be brought into electrical contact with it.

In one embodiment, at least some of the touch-and-close fastener elements have a coating with an electrically conductive material at least in certain sections on their surface. This coating can be applied, for example, by imprinting or dipping.

In one embodiment, on its side having the touch-and-close fastener elements, the substrate is coated, in particular coated with an electrically conductive or semiconducting material, for example printed. The coating can be applied over the entire surface and, if necessary, can then be structured, or coating can take place already structured, for example, by printing using a silk-screen printing process or with inkjet technology. The coating on the side having the touch-and-close fastener elements yields an additional wiring plane. Thus, for example, connecting lines can be applied to the back of the substrate. In conjunction with a substrate that is electrically conductive in certain sections, for example by local changes of the polymer material of the substrate or by local introduction of electrically conductive particles, through-plating from the back of the substrate with the touch-and-close fastener elements to the front of the substrate with the photovoltaic layer can be provided. As a result, contact can be made with the solar cell on the back side.

Other advantages, features and details of the invention will become apparent from the dependent claims and the following description in which several embodiments are detailed with reference to the drawings. The features mentioned in the claims and in the specification can be essential for the invention individually for themselves or in any combination. For purposes of clearer representation, the drawings are not to scale.

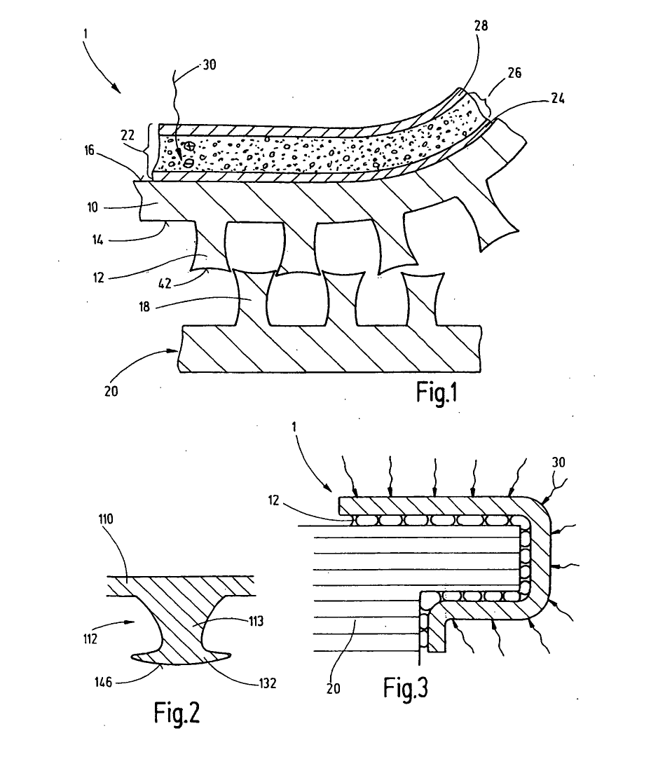

FIG. 1 shows a cross section through a first exemplary embodiment of a solar cell according to the invention,

FIG. 2 shows a cross section through one alternative embodiment of a touch-and-close fastener element,

FIG. 3 shows the attachment of a solar cell according to the invention to a carrier means by means of touch-and-close fastener elements,

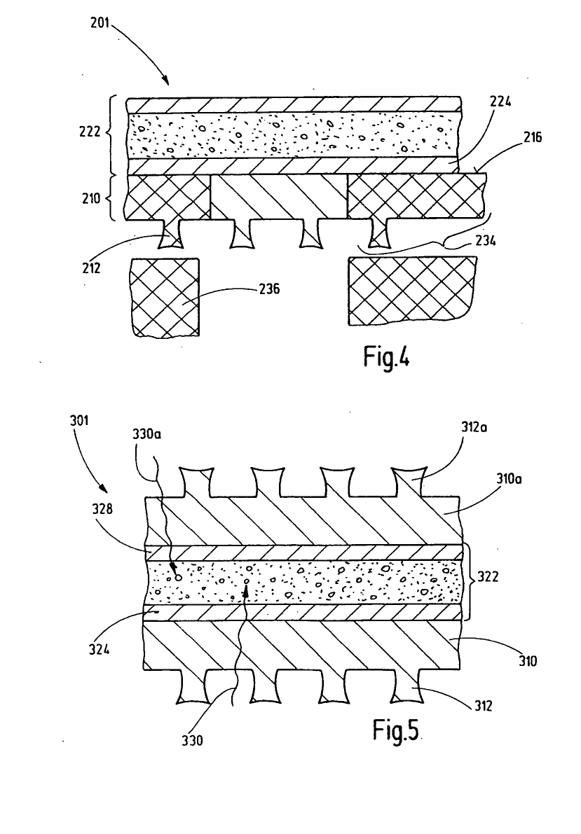

FIG. 4 shows a cross section through a second exemplary embodiment of a solar cell according to the invention, and

FIG. 5 shows a cross section through a third exemplary embodiment of a solar cell according to the invention.

FIG. 1 shows a cross section through a first exemplary embodiment of a solar cell 1 according to the invention. The solar cell 1 has a flexible substrate 10 with a plurality of touch-and-close fastener elements 12 arranged usually in rows and columns. The touch-and-close fastener elements 12 and the substrate 10 are made in one piece. The substrate 10 is made from a polymer plastic, for example a thermoplastic such as polyamide or polypropylene, or from a duroplastic such as polyvinyl siloxane. The touch-and-close fastener elements 12 project obliquely from the first surface 14, preferably at a right angle. The touch-and-close fastener elements 12 can be essentially cylindrical or can have the shape of a hyperboloid. Specifically, they can be axisymmetrical to an axis which extends in the center of the touch-and-close fastener elements 12 and which includes a right angle with the first surface 14. On their end spaced apart from the first surface 14, the touch-and-close fastener elements have a concavely arched surface 42.

The solar cell 1 can be joined to the carrier means 20 having a structure essentially identical to the substrate 10, in particular the touch-and-close fastener elements 12 can be detachably engaged to other touch-and-close fastener elements 18 which are made identically so that the solar cell 10 is detachably fastened to the carrier means 20. Alternatively to fastening the solar cell 1 by means of touch-and-close fastener elements 12, 18, which are interlocked with one another, the touch-and-close fastener elements 12 of the substrate 10 can also be joined to a textile touch-and-close fastener element, for example a fleece or loop material, or directly to a piece of textile clothing or a carrier means with a textile surface.

On the second surface 16 which is opposite a first surface 14, a sequence 22 of layers is applied to the substrate 10 and comprises a first electrode 24, the photovoltaic layer 26, and a second electrode 28, bordering the substrate 10 or bordering an intermediate layer attached to the substrate 10. In the photovoltaic layer 26, incident light 30 is absorbed and, in the process, charge carriers form, in particular electron-hole pairs. The resulting charge carriers are separated and transported to the two electrodes 24, 28 abutting the photovoltaic layer 26 so that an electrical voltage arises on these electrodes 24, 28.

FIG. 1 depicts the incidence of light 30 via the second electrode 28; for this purpose, the second electrode 28 must consist of a material which is transparent or at least partially transparent to the wavelength range of the incident light 30. Electrically conductive or at least semiconducting oxides such as, for example, indium-tin oxide are suitable for this purpose. The thickness of the electrode can be between 50 and 500 nm, preferably between 100 and 300 nm, and in particular between 150 and 250 nm. In one embodiment, the material of the substrate 10 can be transparent or at least partially transparent to the incident light 30. In this case, the light can also be radiated to be incident alternatively or additionally by way of the substrate 10. The electrodes 24, 28 can be blanketing or structured. If one of the electrodes 24, 28 need not be transparent, a metal, for example aluminum, can be used as the material.

In one embodiment, the photovoltaic layer 26 for its part is a multilayer system and can comprise two layers specifically, for example a p-conductive semiconductor polymer, for example poly-3-alkyl thiophenes, conjugated low bandgap polymers or polyphenylene vinylenes, and an organic acceptor as the n-conductor, for example, C60 fullerene derivatives.

The electrodes 24, 28 and/or the photovoltaic layer 26 can be applied structured or unstructured to the substrate 10, for example, by spin coating of a liquid phase. Alternatively, at least some of the layers can also be applied by means of inkjet printer technology by which high resolution electrode geometries can be implemented or the composition of the photovoltaic layer 26 can be varied over the layer thickness.

Alternatively to the first exemplary embodiment of FIG. 1, attachment of the solar cell 1 cannot take place or at least not exclusively by interlocking of the touch-and-close fastener elements 12 with the carrier means 20, but, alternatively or additionally, by adhesion of the touch-and-close fastener elements 12 to a surface of the carrier means 20 of almost any configuration. In this case, it is advantageous if the ends of the touch-and-close fastener elements 12 facing the carrier means 20 can be flexibly deformed so that the ends of the touch-and-close fastener elements 12 make contact to the greatest extent possible with the carrier means 20 with a low contact pressure, preferably solely as a result of the force of gravity acting on the solar cell 10 or as a result of contact pressure which is to be applied manually. To this end, the touch-and-close fastener elements 12 can be modified either on their ends such that they have a low modulus of elasticity, for example by irradiation or exposure in a plasma, or a coating can be applied to the ends of the touch-and-close fastener elements 12. The solar cells 1 which can be attached by means of adhesion forces preferably have a substrate 10 of a duroplastic, in particular of a duroplastic elastomer, for example polyvinyl siloxane.

FIG. 2 shows a cross section through one alternative embodiment of a touch-and-close fastener element 112 which on its end section 132 which is oriented away from the substrate 10 and which faces the carrier means 20 can be modified such that it at least has a modulus of elasticity which has been reduced relative to the adjoining section of the touch-and-close fastener element 112 on the surface 146. The surface section 132 on its free end is arched convexly in order to ensure that contact to the greatest extent possible is made with the carrier means 20 when the section is placed on the carrier means 20. Moreover, the end section 132 has a larger radial extension than the section of the connecting section 113 of the touch-and-close fastener element 112, said former section bordering the end section 132. An articulation site, which can be deflected with small forces and by which extensive contact with the carrier means 20 is ensured, can be formed by the waist-like constriction on the transition of the connecting section 113 to the end section 132 of the touch-and-close fastener element 112.

In one alternative embodiment, greater radial extension of the end section 132 can also take place only in one direction, but then preferably by an amount of at least 20% of the diameter of the section of the connecting section 113 which borders the end section 132. The end section 132 can be formed either by local modification of the material of the touch-and-close fastener element 112, or a suitable material which forms the end section 132 can be applied to the connecting section 113 on the end side, or the end section 132 can be formed in the production of the touch-and-close fastener elements 112, for example by calendering of the touch-and-close fastener elements 112, or can be formed after production by dipping the touch-and-close fastener elements 112 in a suitable solution.

FIG. 3 shows the attachment of a solar cell 1 according to the invention to a carrier means 20 by touch-and-close fastener elements 12. Without additional necessary connecting means or connecting layers, the solar cell 1 can be mounted over a large area as a result of the flexibility of the substrate 10 and the sequence 22 of layers applied to it according to the contour of the surface of the carrier means 20, so that light 30 even from different directions, for example corresponding to the moving position of the sun, can be converted into electrical energy by the solar cell 1.

FIG. 4 shows a cross section through a second exemplary embodiment of a solar cell 201 according to the invention. The substrate 210, which is preferably produced from a thermoplastic, is made electrically conductive in at least one region 234 analogous to the touch-and-close fastener elements 212 located in this region 234 by modification of the plastic, as is indicated by the crosshatching, for example by intercalation of conductive particles. In these regions 234, the substrate 210 makes contact with the sequence 222 of layers located on the second surface 216, in particular the first electrode 224. In this way, it is possible to make electrical contact with the first electrode 224 from the back of the solar cell 201, for example by way of external contact electrodes 236.

FIG. 5 shows a cross section through a third exemplary embodiment of a solar cell 301 according to the invention. On the two sides of the sequence 322 of layers there is one flexible substrate 310, 310a each which, in turn on its side facing away from the sequence 322 of layers, has touch-and-close fastener elements 312, 312a in one piece. One or both substrates 310, 310a are transparent or at least partially transparent to the incident light so that the radiation can be incident via one or both substrates 310, 310a. Attachment to the carrier means 20 can take place alternately by way of one substrate 310 or the other substrate 310a. Electrical contact with the electrodes 324, 328 and therefore with the solar cell 301 can take place in a substrate-free section outside of the section shown in FIG. 5 or by way of the respectively assigned substrate 310, 310a corresponding to the contact-making of the second exemplary embodiment of FIG. 4.

1. A solar cell (1) having a flexible substrate (10), preferably composed of a polymer plastic, and having at least one photovoltaic layer (26) applied to the substrate (10) for converting solar energy into electrical energy, characterized in that the substrate (10) integrally has touch-and-close fastener elements (12) by means of which the substrate (10) and therefore the solar cell (1) can be attached to a carrier means (20) without tools.

2. The solar cell (1) according to claim 1, characterized in that the touch-and-close fastener elements (12) are made in one piece with the substrate (10) which bears the photovoltaic layer (26).

3. The solar cell (1) according to claim 1, characterized in that the substrate (10) on at least one attachment surface, preferably blanketed, has a plurality of touch-and-close fastener elements (12) with a density of more than 100 touch-and-close fastener elements per cm², in particular more than 2,500 touch-and-close fastener elements per cm².

4. The solar cell (1) according to claim 1, characterized in that the substrate (10) on at least one attachment surface, preferably blanketed, has a plurality of touch-and-close fastener elements (12) with a density of more than 10,000 touch-and-close fastener elements per cm², in particular more than 40,000 touch-and-close fastener elements per cm², and preferably more than 250,000 touch-and-close fastener elements per cm².

5. The solar cell (1) according to claim 1, characterized in that at least some of the touch-and-close fastener elements (12) spaced apart from the substrate (10) have an attachment section which, as a result of the force of gravity acting on the solar cell (1) and/or as a result of a contact pressure which can be applied manually, can be brought into flat contact with the carrier means (20) such that the adhesion forces which occur are sufficient to attach the solar cell (1) to the carrier means (20).

6. The solar cell (1) according to claim 1, characterized in that the touch-and-close fastener elements (12) spaced apart from the substrate (10) have a coating with a material whose modulus of elasticity is less than the modulus of elasticity of the touch-and-close fastener element (12).

7. The solar cell (1) according to claim 1, characterized in that at least some of the touch-and-close fastener elements (12) are electrically conductive.

8. The solar cell (1) according to claim 1, characterized in that at least some of the touch-and-close fastener elements (12) have a coating with an electrically conductive material at least in certain sections on their surface.

9. The solar cell (1) according to claim 1, characterized in that the substrate (10) is printed on its side having the touch-and-close fastener elements (12), in particular is printed with an electrically conductive or semiconducting material.

10. The solar cell (1) according to claim 1, characterized in that the substrate (10) is printed structured on its side having the touch-and-close fastener elements (12), preferably is printed using an inkjet printing process, in particular is printed with an electrically conductive or semiconducting material.
